(19) United States
(12) Patent Application Publication
(10) Pub. No.: US 2013/0265735 A1
(43) Pub. Date: Oct. 10, 2013

(54) METAL NANOPARTICLE PASTE, ELECTRONIC COMPONENT ASSEMBLY USING METAL NANOPARTICLE PASTE, LED MODULE, AND METHOD FOR FORMING CIRCUIT FOR PRINTED WIRING BOARD

(71) Applicants: Isao Nakatani, Ibaraki (JP); Masato Hirose, Saitama (JP); Keita Harashima, Saitama (JP); Satoru Kurita, Saitama (JP); Tatsuya Kiyota, Saitama (JP)

(72) Inventors: Isao Nakatani, Ibaraki (JP); Masato Hirose, Saitama (JP); Keita Harashima, Saitama (JP); Satoru Kurita, Saitama (JP); Tatsuya Kiyota, Saitama (JP)

(21) Appl. No.: 13/704,581

(22) PCT Filed: Jun. 2, 2011
(86) PCT No.: PCT/JP2011/062687

§ 371 Date: May 30, 2013

(30) Foreign Application Priority Data
Jun. 16, 2010 (JP) 2010-137494
Dec. 22, 2010 (JP) 2010-286550

(51) Int. Cl. C09D 11/00; H05K 1/18; H05K 1/09

(52) U.S. Cl. CPC C09D 11/52; H05K 1/097; H05K 1/181
USPC 361/783; 174/257; 252/512; 252/514

(57) ABSTRACT

Disclosed is a metal nanoparticle paste that uses the low-temperature sintering characteristics of metal nanoparticles to easily obtain a metal bond with excellent conductivity and mechanical strength, and which can form a wiring pattern with excellent conductivity. The metal nanoparticle paste is characterized by containing (A) metal nanoparticles, (B) a protective film that coats the surface of the metal nanoparticles, (C) a carboxylic acid, and (D) a dispersion medium.

### FIELD OF THE INVENTION

The present invention relates to a metal nanoparticle paste comprising metal nanoparticles having a surface coated with a protective film, and a carboxylic acid. More specifically, the present invention relates to a metal nanoparticle paste which makes it possible to form a wiring pattern on a substrate by a heat treatment at an extremely low temperature when printed by screen printing, ink-jet printing or the like, and a metal nanoparticle paste wherewith an electronic component can be bonded onto a substrate by heating at an extremely low temperature.

### DESCRIPTION OF THE BACKGROUND ART

In the field wherein an electronic component is mounted on a substrate, electrical bonding has been conducted mainly by use of a lead-free solder, particularly a tin-silver-copper alloy solder. Since those solders, however, require extremely high mounting temperature such as 240° C. or more, the solders cannot necessarily be applied to any electrical component or substrate. In the case where a substrate having poor heat resistance such as PET or in the case where low temperature bonding is required from the viewpoint of heat resistance of a module, bismuth or indium-based alloys, which allow an electrical bonding at a relatively low temperature, have been used. However, bismuth has disadvantages of insufficient bonding strength and brittleness of alloys thereof, and indium-based alloys have a disadvantage of being expensive.

In mounting an electronic component or assembling a module for which soldering is not suitable in terms of heat resistance, a silver paste wherewith an electrical bonding can be conducted at a relatively low temperature has been used. A silver paste, however, increases electrical resistance by forming a local cell with a tin electrode, causes Kirkendall void formation, and requires high cost. Meanwhile, a low-melting point metal, an electrically-conductive filler, or metal nanoparticles are added to a silver paste to prevent the increase of electrical resistance.

Examples of a process for producing colloidally-dispersed metal nanoparticles having a coated surface include an evaporation-in-gas process and a reduction-precipitation process (cf. Patent documents 1 and 2). A continuous activated-interface vapor-deposition method is also one of the processes for producing colloidally-dispersed metal nanoparticles having a coated surface. In accordance with said process, colloid of uniformly shaped metal/alloy fine particles with a minimum and uniform size can be obtained by use of a relatively simple apparatus. In addition, the above process can be applied to a variety of metals and alloys (cf. Patent document 3).

Having a large specific area and high reaction activity, metal nanoparticles have a low temperature sintering property whereby the particles are fused at a low temperature, compared with a bulk metal. In the case of silver, for example, it is known that silver nanoparticles are fused and bonded to each other by a heat treatment at a temperature of about 200 to 300° C., which is considerably lower than the original melting point of silver of 964° C., and that the nanoparticles exhibit electrical conductivity at the same level as that in a bulk form.

Recently, heat processes have become more and more complicated, and metal contacts can be exposed to heat several times. In such a case, low melting point alloys such as tin-bismuth alloy involve a problem, i.e., a reduction in bonding reliability due to remelting. As a high melting point solder, which is suitable for an area where a high-temperature and heat-generating component such as a power transistor is mounted, a high-lead solder which could have a negative influence on the environment is still used. Responding to the above situation, the properties of metal nanoparticles (particularly of silver nanoparticles) i.e., a property of sintering at a low temperature and a property of recovering the original melting point of the metal after sintering, are utilized for preventing the reduction in bonding reliability and for maintaining high-temperature resistance of bonding. By use of metal nanoparticles (particularly silver nanoparticles), an electronic component can be bonded onto a substrate and a wiring pattern can be formed, by heating at a temperature considerably lower than the original melting point of the metal, as described above. However, a disadvantage such as high cost has not been overcome.

Patent document 4 proposes a process for forming a wiring pattern using copper nanoparticles at a low temperature in a short period of time. However, since copper is easily oxidized in the atmosphere, as with tin, sintered copper nanoparticles are required to be formed by reducing copper oxide nanoparticles in plasma ambience generated in the presence of a reducing gas. Accordingly, the above technology requires strict control of reaction ambience and use of a special apparatus.

### PRIOR ART DOCUMENTS

Patent document 1: WO 2005/025787
Patent document 2: JP Patent Appl. Publ. No. 2005-26081
Patent document 3: JP Patent Appl. Publ. No. 2008-150630
Patent document 4: JP Patent Appl. Publ. No. 2004-119686

### SUMMARY OF THE INVENTION

### Objective to be Achieved by the Invention

Responding to the above situation, the present invention has an objective of providing a metal nanoparticle paste, wherewith a metallic bonding with excellent electrical conductivity and mechanical properties can be easily obtained, and wherefrom a wiring pattern with excellent electrical conductivity can be formed, by utilizing the low temperature sintering property of the metal nanoparticles.

### Means for Achieving the Objective

In accordance with an embodiment of the metal nanoparticle paste according to the present invention, a metal nanoparticle paste comprises (A) metal nanoparticles, (B) a protective film that coats the surface of said metal nanoparticles, (C) a carboxylic acid, and (D) a dispersion medium. The metal nanoparticles (A) are assumed to be coated with the protective film (B) since the protective film (B) is bonded to the surface of the metal nanoparticles (A) by an intermolecular force caused by an electrostatic force generated between the metal nanoparticles (A) and a compound contained in the protective film (B), i.e., by an electrostatic bond. Since the surface of the metal nanoparticles (A) is coated with the protective film (B), the metal nanoparticle paste can be preserved such that the agglomeration of the metal nanoparticles (A) is prevented in the dispersion medium (D). In contrast, it can be assumed that the bond between the metal nanoparticles (A) and the protective film (B) by an intermolecular force caused by an electrostatic force, is broken and the protective film (B) is separated from the surface of the metal nanopartides (A), by a reaction between the protective film (B) and the carboxylic acid (C) effectuated by heating the metal nanoparticle paste at a predetermined temperature lower than the melting point of the metal nanoparticles, i.e., by low temperature sintering. By the separation of the protective film (B) from the surface of the metal nanoparticles (A) under the above heating condition, the metal nanoparticles are agglomerated and sintered with each other. The term “low temperature sintering” indicates that metal nanoparticles are fused and sintered with each other at a temperature lower than the original melting point of the metal constituting the metal nanoparticles.

In accordance with an embodiment of the metal nanoparticle paste according to the present invention, the metal nanoparticles (A) have a mean primary particle diameter of 1 to 100 nm. In accordance with an embodiment of the metal nanoparticle paste according to the present invention, the metal nanoparticles (A) are particles of at least one metal selected from the group consisting of gold, silver, copper, platinum, palladium, nickel, bismuth, lead, indium, tin, zinc, titanium, aluminum and antimony. In accordance with an embodiment of the metal nanoparticle paste according to present invention, the metal nanoparticles (A) are particles of an alloy of at least one metal selected from the group consisting of gold, silver, copper, platinum, palladium, nickel, bismuth, lead, indium, tin, zinc, titanium, aluminum and antimony. In accordance with an embodiment of the metal nanoparticle paste according to the present invention, the metal nanoparticles (A) are particles of tin having a mean primary particle diameter of 1 to 50 nm.

In accordance with an embodiment of the metal nanoparticle paste according to the present invention, the protective film (B) that coats the surface of metal nanoparticles contains an organic compound having a group containing an oxygen atom, a nitrogen atom or a sulfur atom capable of coordinately bonding to the metal nanoparticles (A) via a lone-electron pair. The metal nanoparticles (A) are assumed to be coated with the protective film (B) since the oxygen, nitrogen or sulfur atom in the organic compound constituting the protective film (B) bonds to the metal nanoparticles (A) by an intermolecular force caused by an electrostatic force.

In accordance with an embodiment of the metal nanoparticle paste according to the present invention, the oxygen atom-containing group is a hydroxy group (—OH) or an oxy group (—O—), the nitrogen atom-containing group is an amino group (—NH₂), and the sulfur atom-containing group is a sulfanyl group (—SH). The metal nanoparticles (A) are assumed to be coated with the protective film (B) since an oxygen atom of the hydroxy group (—OH) or oxy group (—O—), a nitrogen atom of the amino group (—NH₂), or a sulfur atom of the sulfanyl group (—SH) contained in the organic compound constituting the protective film (B) bonds to the metal nanoparticles (A) by an intermolecular force caused by an electrostatic force.

In accordance with an embodiment of the metal nanoparticle paste according to the present invention, the organic compound having the oxygen atom-containing group is a compound represented by the following general formula (I):

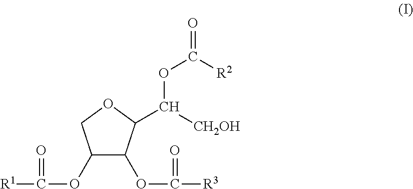

(wherein R¹, R² and R³ are each independently a C₂ to C₂₀ monovalent, and saturated or unsaturated hydrocarbon group). The general formula (I) represents an ester of an intramolecularly dehydrated sugar alcohol and a fatty acid. It can be assumed that the metal nanoparticles (A) are coated with the protective film (B) since an oxygen atom of the hydroxy group (—OH) in the intramolecularly dehydrated sugar alcohol bonds to the surface of the metal nanoparticles (A) by an intermolecular force caused by an electrostatic force. In contrast, the protective film (B) can be assumed to be separated from the surface of the metal nanoparticles (A) by a reaction between the sugar alcohol fatty acid ester of the general formula (I) and a carboxylic acid such as a monocarboxylic acid represented by the following general formula (II) or a dicarboxylic acid represented by the following general formula (III), namely by a reaction between a hydroxy group of the sugar alcohol and a carboxyl group of the carboxylic acid. In accordance with an embodiment of the metal nanoparticle paste according to the present invention, the organic compound having the nitrogen atom-containing group is a compound represented by the following general formula (IV):

R⁶—NH₂ (IV)

(wherein R⁶ is a C₂ to C₂₀ monovalent, and saturated or unsaturated hydrocarbon group). The general formula (IV) represents an amine, and the metal nanoparticles (A) are assumed to be coated with the protective film (B) since a nitrogen atom of the amino group bonds to the surface of the metal nanoparticles (A) by an intermolecular force caused by an electrostatic force.

In accordance with an embodiment of the metal nanoparticle paste according to the present invention, the carboxylic acid (C) is a monocarboxylic acid or an anhydride thereof, or a dicarboxylic acid or an anhydride thereof. In accordance with an embodiment of the metal nanoparticle paste according to the present invention, the monocarboxylic acid is a compound represented by the following general formula (II):

R⁴—COOH (II)

(wherein R⁴ is a C₆ to C₁₀ monovalent, and saturated or unsaturated hydrocarbon group). In accordance with an embodiment of the metal nanoparticle paste according to the present invention, the dicarboxylic acid is represented by the following general formula (III):

HOOC—R⁵—COOH (III)
(wherein R⁵ is a C₁ to C₁₂ divalent group, which can have an ether bond).

In accordance with an embodiment of the metal nanoparticle paste according to the present invention, the metal nanoparticles (A) contain silver and the dispersion medium (D) is a terpene alcohol. That means, the kind of the metal constituting the metal nanoparticles (A) is silver or a metal containing at least silver.

In accordance with an embodiment of the electronic component assembly according to the present invention, an electronic component is mounted on a substrate by use of the above metal nanoparticle paste. In this embodiment, the above metal nanoparticle paste is used as an electrically conductive bonding material between the substrate and the electronic component.

In accordance with an embodiment of the LED module according to the present invention, an LED element is bonded to a substrate by use of the above metal nanoparticle paste.

In accordance with an embodiment of the process for forming a circuit on a printed wiring board according to the present invention, an electrode and a wiring pattern are formed by a screen printing method or an ink-jet method by use of the above metal nanoparticle paste, and said wiring pattern is calcined by heating at a temperature of 250° C. or more. In this embodiment, the above metal nanoparticle paste is used as a wiring material on a substrate.

### Effects of the Invention

In accordance with the present invention, a metallic bonding excelling in electrical conductivity and mechanical strength can be obtained and a wiring pattern excelling in electrical conductivity can be formed, easily and at a low cost by utilizing the low temperature sintering property of metal nanoparticles. In accordance with the present invention, agglomeration of metal nanoparticles can be prevented and thereby the dispersion stability can be improved during the preservation of the metal nanoparticle paste, since the surface of the metal nanoparticles is coated with a protective film. Moreover, since the protective film is separated from the surface of the metal nanoparticles by heating the metal nanoparticle paste at a temperature lower than the melting point of the metal nanoparticles constituting the paste, the metal nanoparticles can be easily agglomerated and sintered, whereas excellent dispersion stability is maintained during the preservation.

Particularly, a coating film exhibiting not only excellent electrical conductivity and mechanical strength, but also a high reflectance, can be obtained by use of a metal nanoparticle paste wherein a terpene alcohol is used as a dispersion medium for silver-containing metal nanoparticles. A metal nanoparticle paste containing silver has excellent electrical conductivity, as well as high thermal conductivity and a thermal dissipation property. Thus, since the metal nanoparticle paste obtained by adding silver-containing metal nanoparticles and a terpene alcohol also exhibits excellent reflectance and thermal conductivity, excellent reflectance can be imparted to a circuit board for example by applying the paste onto the surface thereof. At the same time, the above paste is suitable as a bonding material used for bonding electronic components such as an LED element.

### BRIEF DESCRIPTION OF FIGURES AND DRAWINGS

FIG. 1 shows a reflow heating profile in the case of using the metal nanoparticles of tin or soldering powder.

FIG. 2 shows a reflow heating profile in the case of using the metal nanoparticles of silver or copper.

FIG. 3 shows a reflow heating profile in the case of using the metal nanoparticles of silver.

FIG. 4 shows a second reflow heating profile in the case of using the metal nanoparticles of silver.

### DESCRIPTION OF EMBODIMENTS FOR CARRYING OUT THE INVENTION

The metal nanoparticle paste according to the present invention is described in the following section. The metal nanoparticle paste according to the present invention is a mixture comprising (A) metal nanoparticles, (B) a protective film that coats the surface of the metal nanoparticles, (C) a carboxylic acid and (D) a dispersion medium.

(A) Metal Nanoparticles

The metal nanoparticles used as the component (A) are a metal powder having a nano-order mean primary particle diameter. Having such a nano-order mean primary particle diameter, the metal nanoparticles have a large specific surface area and enhanced reaction activity, and thereby an electronic component can be electrically bonded onto a substrate and a wiring pattern can be formed on a substrate, at a heating temperature considerably lower than the original melting point of the metal. The kinds of a metal constituting the metal nanoparticles are not particularly limited if the particles have a good electrical conductivity and can be coated with the protective film used as the component (B) described below. The metals are exemplified by single metals used for soldering, such as gold, silver, copper, platinum, palladium, nickel, bismuth, lead, iridium, tin, zinc, titanium, aluminum and antimony, or alloys thereof. Among the above metals, tin and copper are preferable from the viewpoint of environmental load, cost and prevention of migration.

When the metal nanoparticle paste is used as an electrically conductive bonding material for bonding an LED element onto a circuit board, silver is preferable as the above metal for obtaining a super luminosity LED module.

The upper limit of the mean primary particle diameter of the metal nanoparticles is 100 nm for obtaining a low temperature sintering property, preferably 50 nm for rapidly effectuating low temperature sintering, and particularly preferably 20 nm for applying the paste to a precise area onto which an electronic component is bonded and for forming a fine wiring pattern. The lower limit of the mean primary particle diameter of the metal nanoparticles is 1 nm for dispersion stability, preferably 2 nm for a low temperature sintering property, and particularly preferably 3 nm for production stability. The metal nanoparticles can be used alone or in a mixture of two or more kinds.

(B) Protective Film that Coats the Surface of the Metal Nanoparticles

The protective film that coats the surface of the metal nanoparticles used as the component (B) is used for preventing metal nanoparticles from fusing to each other due to the high reaction activity of the surface of the metal nanoparticles (A), and for uniformly dispersing the metal nanoparticles in a dispersion medium, i.e., for imparting dispersion stability to the metal nanoparticles. The components of the protective film are not particularly limited if said components are compounds wherewith the surface of the metal nanoparticles can be coated and whereby the metal nanoparticles can exhibit uniform dispersibility in the dispersion medium. Examples thereof are organic compounds having a group containing an oxygen atom, a nitrogen atom or a sulfur atom being capable of coordinately bonding to the metal nanoparticles via a lone-electron pair. The protective film coats the metal nanoparticles since the above oxygen, nitrogen or sulfur atom bonds to the surface of the metal nanoparticles by an intermolecular force caused by an electrostatic force. Moreover, since the organic compound has a compatibility with a dispersion medium such as an organic solvent, the metal nanoparticles can have dispersion stability. The oxygen atom-containing groups are exemplified by a hydroxy group (—OH) and an oxy group (—O—), the nitrogen atom-containing groups are exemplified by an amino group (—NH₂), and the sulfur atom-containing groups are exemplified by a sulfanyl group (—SH).

A preferable example of the organic compound used as a component of the protective film is an organic compound having a group containing an oxygen atom, a nitrogen atom or a sulfur atom capable of coordinately bonding to the metal nanoparticles via a lone-electron pair, and having a C₂ to C₂₀ saturated or unsaturated hydrocarbon group, from the viewpoints of thermal stability at room temperature and of dispersibility of the metal nanoparticles. A particularly preferable example is an organic compound having a group containing an oxygen atom, a nitrogen atom or a sulfur atom capable of coordinately bonding to the metal nanoparticles via a lone-electron pair, and having a plurality of C₄ to C₁₈ saturated or unsaturated hydrocarbon groups.

Examples of the above organic compound used as a component of the protective film are esters of sugar alcohols and fatty acids. The sugar alcohols are not particularly limited and can be exemplified by glycerin, sorbitol and intramolecularly dehydrated sorbitol, mannitol and intramolecularly dehydrated mannitol, xylitol and intramolecularly dehydrated xylitol, and erythritol and intramolecularly dehydrated erythritol. The fatty acids are not particularly limited and can be exemplified by butyric acid, caproic acid, enanthic acid, caprylic acid, capric acid, lauric acid, myristic acid, palmitic acid, stearic acid, and oleic acid. An example of the sugar alcohol fatty acid ester is an ester of an intramolecularly dehydrated sugar alcohol and a fatty acid, represented by the following general formula (I):

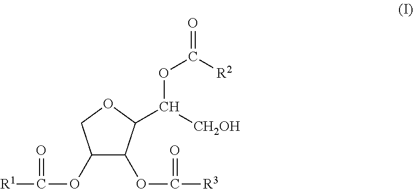

(wherein R¹, R² and R³ are each independently a C₂ to C₂₀ monovalent, and saturated or unsaturated hydrocarbon group), which is specifically exemplified by a compound represented by the following formula (I-1):

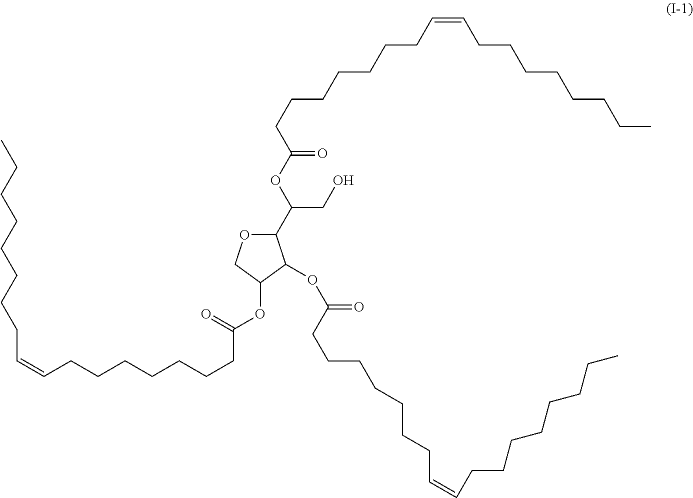 [SMILES: CCCCCCCC/C=C\CCCCCCCC(=O)OC(CO)C1OCC(OC(=O)CCCCCCC/C=C\CCCCCCCC)C1OC(=O)CCCCCCC/C=C\CCCCCCCC]

Additionally, an example of the organic compound used as a component of the protective film is an amine represented by the following general formula (IV):

R⁶—NH₂ (IV)

(wherein R⁶ is a C₂ to C₂₀ monovalent, and saturated or unsaturated hydrocarbon group), which is specifically exemplified by a compound represented by the following formula (IV-1):

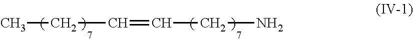

The upper limit of the amount of the protective film that coats the metal nanoparticles is 30 parts by weight on the basis of 100 parts by weight of the metal nanoparticles, for preventing electrical resistance increase, and is preferably 20 parts by weight for obtaining a low temperature sintering property. In contrast, the lower limit of the amount of the protective film that coats the metal nanoparticles is 5 parts by weight on the basis of 100 parts by weight of the metal nanoparticles, for maintaining the dispersion stability of the metal nanoparticles at room temperature, and preferably 10 parts by weight for successfully obtaining the dispersion stability. The above components of the protective film can be used alone or in a mixture of two or more thereof.

Processes for producing metal nanoparticles coated with the protective film used as the component (B) are not particularly limited. The continuous activated-interface vapor-deposition method as disclosed in the above Patent document 3 is preferable since colloid of metal/alloy fine particles having a uniform size and shape can be easily produced thereby, and nanoparticles of easily-oxidized base metals such as tin, copper and nickel, can be produced in the state of pure metals.

In accordance with the activated continuous-interface vapor-deposition method, an apparatus composed of a rotating vacuum tank wherein a liquid medium is pooled in the lower part thereof, a system for evaporating a metal material placed in said rotating vacuum tank, and a variable-speed rotating system whereby said rotating vacuum tank is rotated around the central axis thereof, is used.

In accordance with the activated continuous-interface vapor-deposition method, a solution (e.g., an alkylnaphthalene solution) containing 10% by weight of a component of the protective film (e.g., sorbitan fatty acid ester) is charged into the rotating vacuum tank in a predetermined amount (e.g., 200 ml), and a predetermined amount (e.g., 10 g) of a metal lump, as a raw material of the metal nanoparticles, is charged into a resistance heated evaporation source. The rotating vacuum tank is rotated at a predetermined rotation rate (e.g., 100 mm/s) while evacuation of the tank is conducted, and the resistance heated evaporation source is heated in a vacuum of 5×10⁻⁵ Torr to evaporate a metal vapor at a predetermined rate (e.g., 0.2 g/min). By the operation for a predetermined time length (e.g., 120 minutes) under the above conditions, the metal lump nearly disappears and evaporated metal is adsorbed to the solution and thereby colloid of metal nanoparticles can be obtained in the bottom part of the rotating vacuum tank. A solution (e.g., cyclohexane solution) is volatilized from the obtained colloid of metal nanoparticles, and thereby metal nanoparticles coated with a protective film can be obtained.

(C) Carboxylic Acid

A carboxylic acid used as the component (C) reacts with the protective film coating the metal nanoparticles under a predetermined heating condition, i.e., at a heating temperature lower than the original melting point of a metal constituting the metal nanoparticles. Thereby, the protective film is separated from the surface of the metal nanoparticles and the function as a protective film is lost. The protective film is separated from the surface of the metal nanoparticles under the above heating condition, and thereby the agglomeration and sintering of the metal nanoparticles occur. In other words, the carboxylic acid serves as a protective film separating agent. For example, the carboxylic acid reacts with a group containing an oxygen, nitrogen or sulfur atom capable of coordinately bonding to the metal nanoparticles via a lone-electron pair, which is contained in the organic compound constituting the protective film.

The above is more specifically described on the basis of an example using a sugar alcohol fatty acid ester represented by the general formula (I) as the component of the preventing film. By esterification of a carboxyl group of a carboxylic acid through a reaction with a hydroxyl group of an intramolecularly dehydrated sugar alcohol, a bond between the sugar alcohol fatty acid ester and the metal nanoparticles by an intermolecular force caused by the hydroxy group of the sugar alcohol is broken. As a result, the protective film is separated from the surface of the metal nanoparticles. In addition, on the basis of an example using an amine represented by the general formula (IV) as a component of the protective film, an amino group of the amine is amidated through a reaction with a carboxyl group of the carboxylic acid, and thereby a bond between the amine and the metal nanoparticles by an intermolecular force caused by the amino group is broken. As a result, the protective film is separated from the surface of the metal nanoparticles.

Carboxylic acids which can be mixed with the metal nanoparticle paste are not particularly limited if the carboxylic acids are carboxyl group-containing organic compounds such as a monocarboxylic acid and an anhydride thereof, a dicarboxylic acid and an anhydride thereof, and a tricarboxylic acid and an anhydride thereof. Examples of the monocarboxylic acid are compounds represented by the general formula (II):

R⁴—COOH (II)

(wherein R⁴ is a C₆ to C₁₀ monovalent, and saturated or unsaturated hydrocarbon group). Said compounds are exemplified by: saturated fatty acids such as heptanoic acid, octanoic acid, nonanoic acid, decanoic acid and an anhydride thereof; and unsaturated fatty acids such as trans-3-hexenoic acid and 2-nonenoic acid and an anhydride thereof. From the viewpoint of capability of smoothly separating the protective film, nonanoic acid is preferable. Examples of the dicarboxylic acid are compounds represented by the general formula (III):

HOOC—R⁵—COOH

(wherein R⁵ is a C₁ to C₁₂ divalent group, which can have an ether bond). The compounds are exemplified by glutaric acid, adipic acid, suberic acid, diglycolic acid, succinic acid, phthalic acid, and an anhydride and a derivative thereof. From the viewpoint of resistance against residue deposition and of capability of smoothly separating the protective film, diglycolic acid, an anhydride of diglycolic acid and an anhydride of succinic acid are preferable. Examples of the tricarboxylic acid are citric acid, isocitric acid and aconitic acid.

The upper limit of the amount of the carboxylic acid to be added is 300 parts by weight on the basis of 100 parts by weight of metal nanoparticles coated with the protective film, from the viewpoint of prevention of the oxidation of the metal nanoparticles, by the carboxylic acid. To obtain a predetermined metal ratio to the entire metal nanoparticle paste, the above amount is preferably 200 parts by weight. The lower limit of the carboxylic acid is 30 parts by weight on the basis of 100 parts by weight of the metal nanoparticles coated with the protective film, from the viewpoint of ensuring the separation of the protective film from the surface of the metal nanoparticles, and is preferably 40 parts by weight from the viewpoint of the stabilization of electrical conductivity. The above carboxylic acids can be used alone or in a mixture of two or more kinds.

(D) Dispersion Medium

The dispersion medium used as the component (D) adjusts the viscosity of the metal nanoparticle paste and serves as a lubricating agent for the transfer of the metal nanoparticles in the metal nanoparticle paste during low temperature sintering. Examples of the dispersion medium are saturated or unsaturated aliphatic hydrocarbons such as decane, tetradecane, and octadecane; ketones such as methylethyl ketone, and cyclohexanone; aromatic hydrocarbons such as toluene, xylene, and tetramethylbenzene; glycol ethers such as methylcellosolve, ethylcellosolve, butylcellosolve, methylcarbitol, butylcarbitol, propyleneglycolmonomethylether, die thyleneglycolmonomethylether, diethyleneglycolmonoethylether, dipropyleneglycolmonomethylether, and triethyleneglycolmonoethylether; esters such as ethylacetate, butylacetate, cellosolveacetate, diethyleneglycolmonomethyletheracetate, diethyleneglycolmonoethyletheracetate, propyleneglycolmonomethyletheracetate, and esterified products of the above glycol ethers; alcohols such as ethanol, propanol, ethyleneglycol, propyleneglycol and hexyldiglycol; and C₃₀ or more unsaturated hydrocarbons such as squalane.

As the dispersion medium, terpene alcohols such as monoterpene alcohol, sesquiterpene alcohol, and diterpene alcohol can be used. Particularly, in the case of using silver-containing nanoparticles as the metal nanoparticles, a metal nanoparticle paste, which can form a coating film with excellent electrical conductivity and a high reflectance, can be obtained by use of the above terpene alcohols as the dispersion medium. The monoterpene alcohols are exemplified by α-terpineol, β-terpineol, γ-terpineol, b-terpineol, manool, borneol, terpinen-4-ol, and dihydroterpineols such as 1-hydroxy-p-menthane and 8-hydroxy-p-menthane. The sesquiterpene alcohols are exemplified by carotol, cedrol, nerolidol, patchoulol, α-bisabolol, viridiflorol, and cadinol.

The dispersion medium is preferably an organic solvent having a flash point of 50° C. or more and a boiling point of 150° C. or more, from the viewpoint of stable preservation at room temperature and inhibition of evaporation during low temperature sintering. An example of the organic solvent is hexyldiglycol. Moreover, from the viewpoint of function as a lubricating agent during low temperature sintering, an organic solvent having a boiling point not lower than a temperature at which the protective film used as the component (B) is separated from the surface of the metal nanoparticles, is particularly preferable. Such organic solvents are exemplified by squalane and tetradecane having a boiling point of 250° C. or more.

The amount of the dispersion medium to be added can be appropriately determined in accordance with the desired viscosity, and, on the basis of 100 parts by weight of the metal nanoparticles coated with the protective film, the mixing amount is, for example, 1 to 300 parts by weight, and preferably 20 to 200 parts by weight from the viewpoint of the prevention of cracks on a coating film. The viscosity of the metal nanoparticle paste measured with a B-type viscometer is, for example, 5 Pa·s to 400 Pa·s at 25° C., preferably 20 Pa·s to 300 Pa·s at 25° C. from the viewpoint of coating workability, and more preferably 50 Pa·s to 200 Pa·s at 25° C. from the viewpoint of ease of coating implementation by screen printing or by use of a dispenser and from the viewpoint of a function as a lubricating agent. The above dispersion media can be used alone or in a mixture of two or more thereof.

Conventional additives can be mixed with the metal nanoparticle paste, if needed, in accordance with use. Examples of the additives are glazing agents, metal corrosion inhibitors, stabilizers, flow improvers, dispersion stabilizers, thickeners, viscosity modifiers, moisturizing agents, thixotropic agents, defoaming agents, bactericides, and fillers. The above additives can be used alone or in a mixture of two or more kinds.

In the following section, a process for producing the metal nanoparticle paste according to the present invention is described. The process for producing the metal nanoparticle paste is not particularly limited. The metal nanoparticle paste according to the present invention can be obtained, for example, by adding metal nanoparticles coated with a protective film produced by a predetermined process (e.g., continuous activated-interface vapor-deposition method) and a carboxylic acid to a predetermined dispersion medium, and by dispersing the same.

In the following section, examples of an application and a method of use of the metal nanoparticle paste according to the present invention are described. The metal nanoparticle paste according to the present invention can be used for a variety of applications. The metal nanoparticle paste according to the present invention contains metal nanoparticles at a high density, and can be sintered at a temperature lower than the melting point of the metal nanoparticles (e.g., about 150 to 200° C. in the case of tin, and about 250 to 350° C. in the case of silver or copper). Since having a low temperature sintering property as described above, the metal nanoparticle paste is used, for example, as an electrically conductive bonding material wherewith an electronic component is electrically and physically bonded onto a wiring substrate, or as a film material for forming an electrically conductive film, particularly as a wiring material for forming a wiring pattern on a substrate.

In the case of using the metal nanoparticle paste as an electrically conductive bonding material, the metal nanoparticle paste is applied to the position on a wiring substrate, to which an electronic component is bonded, the electronic component is mounted on the film of the applied metal nanoparticle paste and calcined. Thereby, the electronic component is bonded onto the wiring substrate. Methods for the application of the metal nanoparticle paste are not particularly limited, and can be exemplified by a screen printing method and a dispenser method. The amount of the metal nanoparticle paste to be applied can be appropriately adjusted, and the paste is applied, for example, in a thickness of 1 to 20 μm. Calcination temperature is not particularly limited if it is a temperature at which a protective film coating the surface of the metal nanoparticles is separated therefrom, and the metal nanoparticles are fused with each other and sintered at a low temperature. In the case where the metal nanoparticles are tin particles and the protective film is formed from the sorbitan fatty acid ester of the formula (I-1), the calcination temperature is 150 to 200° C., preferably 150 to 170° C. In the case where the metal nanoparticles are copper or silver particles and the protective film is formed from the sorbitan fatty acid ester of the formula (I-1), the calcination temperature is 250 to 350° C., preferably 280 to 320° C. The calcination time length can be appropriately selected, and is 5 to 120 minutes, for example. Materials of wiring substrates to be used are not particularly limited, and inorganic materials such as glass and metal oxides can be used. Since the metal nanoparticle paste according to the present invention has a low temperature sintering property, organic materials such as polyester resins, polycarbonate resins, styrene resins and fluorine resins can also be used, though those organic materials are inferior to the inorganic materials in terms of heat resistance.

According to the above example of a method of use, an electronic component can also be bonded to a fine area of a wiring substrate since the metal particles are nano-sized particles. For example, bonding can be conducted by use of the metal nanoparticle paste according to the present invention also on a 0402 chip or on a 0.3 mm or less fine pitch mounting area, in contrast to a bonding which has the disadvantage of inconstancy in the supply of printed soldering paste caused by conventional soldering.

In the case of use as a wiring material, a desired wiring pattern is drawn on a substrate with the metal nanoparticle paste, the drawn wiring pattern is calcined to form a sintered wiring pattern on a substrate. The method for applying the metal nanoparticle paste is not particularly limited if a wiring pattern can be formed thereby, and is exemplified by a screen printing method or an ink-jet printing method. The amount of the metal nanoparticle paste to be applied, calcination conditions and materials usable as a substrate are the same as those described in the above use as an electrically conductive bonding material. The above method of use can also be applied to the foniiation of a fine wiring pattern by utilizing the nano-size of the metal particles.

In addition, the metal nanoparticle paste according to the present invention can form a coating film having an excellent electrical conductivity and high reflectance by use of silver-containing metal nanoparticles and a terpene alcohol as a dispersion medium. Thus, the metal nanopartide paste can be used as a reflective coating film/bonding material in the production of an LED module by bonding an LED element by use of Die Bonder to a circuit substrate onto which the metal nanoparticle paste has been applied.

### EXAMPLES

In the following section, the present invention is further described in detail on the basis of examples. The present invention is, however, not limited to the embodiments of the examples described below.

### Examples 1 to 11

### Comparative Examples 1 to 6

Examples wherein the metal nanoparticle paste according to the present invention is used as an electrically conductive bonding material are described in the following section.

(1) Components of the Metal Nanoparticle Paste:

### Electrically Conductive Material:

Concerning metal nanoparticles coated with protective film (hereinafter referred to as “coated metal nanoparticles”):

### Coated Metal Nanoparticles I:

tin nanoparticles coated with a protective film consisting of the sorbitan fatty acid ester of the formula (I-1), by the above activated continuous-interface vapor-deposition method

### Coated Metal Nanoparticles II:

tin nanoparticles coated with a protective film consisting of the oleyl amine of the formula (IV-1), by the above activated continuous-interface vapor-deposition method

### Coated Metal Nanoparticles III:

silver nanoparticles coated with a protective film consisting of the sorbitan fatty acid ester of the formula (I-1), by the above activated continuous-interface vapor-deposition method

### Coated Metal Nanoparticles IV:

copper nanoparticles coated with a protective film consisting of the sorbitan fatty acid ester of the formula (I-1), by the above activated continuous-interface vapor-deposition method
According to a thermal analysis (TG-DTA method), the contents of the protective film components of the above coated metal nanoparticles I to IV were each proved to be 20% by weight.

Concerning metal powder:

SAC 305 soldering powder: produced by K.K. Tamura Seisakusho by a centrifugal atomization process
Dry-powder tin nanoparticles: particles not coated with a protective film, “Tin nanopowder” produced by Aldrich

(2) Process for Producing Metal Nanoparticle Paste Used as an Electrically Conductive Bonding Material

A predetermined amount of a cyclohexane dispersion containing 20% by weight of the above coated metal nanoparticles obtained by the activated continuous-interface vapor-deposition method was poured into an agate mortar, and the contained cyclohexane was completely volatilized by drying under a reduced pressure. Thereby, coated metal nanoparticles containing 20% by weight of the protective film component were obtained. Predetermined amounts of a carboxylic acid and a solvent were added to the coated metal nanoparticles and the content was mixed for 5 minutes with a pestle. Thereby, a metal nanoparticle paste to be used as an electrically conductive bonding material was obtained.

In accordance with the above process for producing an electrically conductive bonding material, metal nanoparticle pastes of Examples 1 to 11 and Comparative Examples 1 to 6 were prepared by mixing the components in the proportions as summarized in the following Table 1. The unit of the values of the mixing proportion is % by weight.

TABLE 1

| | | | | Exam- | Exam- | Exam- | Exam- | Exam- | Exam- | Exam- | Exam- | Exam- | Exam- |
|---|---|---|---|---|---|---|---|---|---|---|---|---|---|
| | | | | ple 1 | ple 2 | ple 3 | ple 4 | ple 5 | ple 6 | ple 7 | ple 8 | ple 9 | ple 10 |
| mixing | electri- | coated | metal: tin | 50 | 55 | 40 | 30 | — | 50 | 50 | 50 | — | — |
| propor- | cally | metal nano- | (mean primary | | | | | | | | | | |
| tion | con- | particles I | particle | | | | | | | | | | |
| (% by | ductive | | diameter 10 nm) | | | | | | | | | | |
| weight) | mate- | coated | metal: tin | — | — | — | — | 50 | — | — | — | — | — |
| | rials | metal nano- | (mean primary | | | | | | | | | | |
| | | particles II | particle | | | | | | | | | | |
| | | | diameter 50 nm) | | | | | | | | | | |
| | | coated | metal: silver | — | — | — | — | — | — | — | — | 50 | |
| | | metal nano- | (mean primary | | | | | | | | | | |
| | | particles III | particle | | | | | | | | | | |
| | | | diameter 4.6 nm) | | | | | | | | | | |
| | | coated | metal: copper | — | — | — | — | — | — | — | — | — | 50 |
| | | metal nano- | (mean primary | | | | | | | | | | |
| | | particles IV | particle | | | | | | | | | | |
| | | | diameter 5.0 nm) | | | | | | | | | | |
| | | metal | SAC305 | — | — | — | — | — | — | — | — | — | — |
| | | powder | soldering | | | | | | | | | | |
| | | | powder (mean | | | | | | | | | | |
| | | | primary particle | | | | | | | | | | |
| | | | diameter 3.6 μm) | | | | | | | | | | |
| | | | dry powder tin | — | — | — | — | — | — | — | — | — | — |
| | | | nanoparticles | | | | | | | | | | |
| | | | (mean primary | | | | | | | | | | |
| | | | particle | | | | | | | | | | |
| | | | diameter 1.50 nm) | | | | | | | | | | |
| | carboxylic | | diglycolic acid | 30 | 25 | 40 | 50 | 30 | — | — | — | — | — |
| | acids | | diglycolic | — | — | — | — | — | 30 | — | — | — | — |
| | | | anhydride | | | | | | | | | | |
| | | | nonane acid | — | — | — | — | — | — | 30 | — | — | — |
| | | | octenyl succinic | — | — | — | — | — | — | — | 30 | 30 | 30 |
| | | | anhydride | | | | | | | | | | |
| | amine | | oleylamine | — | — | — | — | — | — | — | — | — | — |
| | halogen-based | | dibromo- | — | — | — | — | — | — | — | — | — | — |
| | activator | | butenediol | | | | | | | | | | |
| | others | dispersion | hexyldiglycol | 20 | 20 | 20 | 20 | 20 | 20 | 20 | 20 | — | — |
| | | medium | squalene | — | — | — | — | — | — | — | — | 20 | 20 |
| | | flux | dedicated | — | — | — | — | — | — | — | — | — | — |
| | | | vehicle | | | | | | | | | | |
| | | | MSPJ02 | | | | | | | | | | |
| | | | (in-house | | | | | | | | | | |
| | | | semi product) | | | | | | | | | | |

| | | | | | | | | | | |
|---|---|---|---|---|---|---|---|---|---|---|
| Total | 100 | 100 | 100 | 100 | 100 | 100 | 100 | 100 | 100 | 100 |

| | | | | | Compara- | Compara- | Compara- | Compara- | Compara- | Compara- |
|---|---|---|---|---|---|---|---|---|---|---|
| | | | | Exam- | tive | tive | tive | tive | tive | tive |
| | | | | ple 11 | Example 1 | Example 2 | Example 3 | Example 4 | Example 5 | Example 6 |
| mixing | electri- | coated | metal: tin | 48.25 | 50 | — | 50 | 50 | — | — |
| propor- | cally | metal nano- | (mean primary | | | | | | | |
| tion | con- | particles I | particle | | | | | | | |
| (% by | ductive | | diameter 10 nm) | | | | | | | |
| weight) | mate- | coated | metal: tin | — | — | — | — | — | — | — |
| | rials | metal nano- | (mean primary | | | | | | | |
| | | particles II | particle | | | | | | | |
| | | | diameter 50 nm) | | | | | | | |
| | | coated | metal: silver | 1.5 | — | — | — | — | — | — |
| | | metal nano- | (mean primary | | | | | | | |
| | | particles III | particle | | | | | | | |
| | | | diameter 4.6 nm) | | | | | | | |
| | | coated | metal: copper | 0.25 | — | — | — | — | — | — |
| | | metal nano- | (mean primary | | | | | | | |
| | | particles IV | particle | | | | | | | |
| | | | diameter 5.0 nm) | | | | | | | |
| | | metal | SAC305 | — | — | — | — | — | 40 | 50 |
| | | powder | soldering | | | | | | | |
| | | | powder (mean | | | | | | | |
| | | | primary particle | | | | | | | |
| | | | diameter 3.6 μm) | | | | | | | |
| | | | dry powder tin | — | — | 50 | — | — | — | — |
| | | | nanoparticles | | | | | | | |
| | | | (mean primary | | | | | | | |
| | | | particle | | | | | | | |
| | | | diameter 1.50 nm) | | | | | | | |

| carboxylic | | diglycolic acid | 30 | — | 30 | — | — | — | 30 |
|---|---|---|---|---|---|---|---|---|---|
| acids | | diglycolic | — | — | — | — | — | — | — |
| | | anhydride | | | | | | | |
| | | nonane acid | — | — | — | — | — | — | — |
| | | octenyl succinic | — | — | — | — | — | — | — |
| | | anhydride | | | | | | | |
| amine | | oleylamine | — | — | — | 30 | — | — | — |
| halogen-based | | dibromo- | — | — | — | — | 30 | — | — |
| activator | | butenediol | | | | | | | |
| others | dispersion | hexyldiglycol | 20 | 50 | 20 | 20 | 20 | — | 20 |
| | medium | squalene | — | — | — | — | — | — | — |
| | flux | dedicated | — | — | — | — | — | 60 | — |
| | | vehicle | | | | | | | |
| | | MSPJ02 | | | | | | | |
| | | (in-house | | | | | | | |
| | | semi product) | | | | | | | |

| | | | | | | | |
|---|---|---|---|---|---|---|---|
| Total | 100 | 100 | 100 | 100 | 100 | 100 | 100 |

(3) Performance Evaluation

### (I) Chip Resistance:

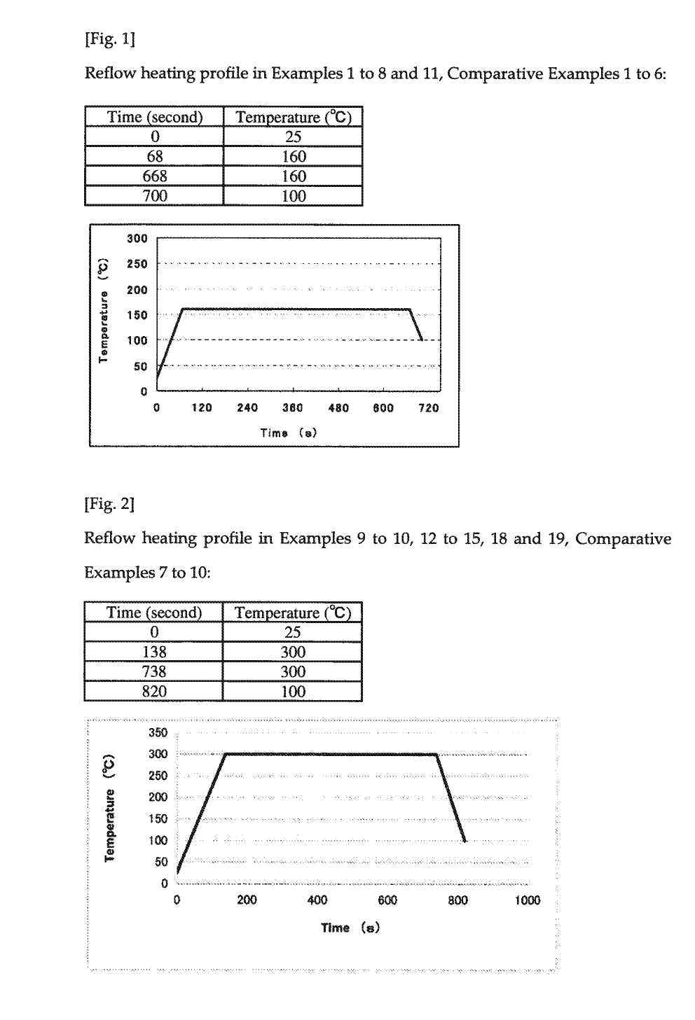

On a glass epoxy substrate having a surface on which copper-foil lands are formed, a metal nanoparticle paste produced as described above was printed with a metal mask having a thickness of 200 μm by use of a metal squeegee. A tinned 1608CR chip having a resistance of 0Ω was mounted thereon by use of a chip mounter produced by YAMAHA K.K. The 1608CR chip mounted on the glass epoxy substrate was bonded by reflow heating (with the reflow profile shown in FIG. 1 (oxygen concentration during reflow heating: 50 ppm or less) in Examples 1 to 8 and Comparative Examples 1, 3 to 4 wherein coated metal nanoparticles of tin were mixed, Comparative Example 2 wherein dry powder tin nanoparticles were mixed, Comparative Examples 5 and 6 wherein SAC305 soldering powder was mixed, and Example 11 wherein coated metal nanoparticles of tin, coated metal nanoparticles of silver and coated metal nanoparticles of copper were mixed such that the same composition as that of SAC305 soldering powder could be obtained; and with the reflow profile shown in FIG. 2 (oxygen concentration during reflow heating: 50 ppm or less) in Examples 9 and 10 wherein coated metal nanoparticles of silver or copper were mixed). The values of resistance of the obtained assemblies were measured with a micrometer produced by Iwatsu Keisoku K.K.

### (II) Shearing Strength of Chip Resistor:

On a glass epoxy substrate having a surface on which copper-foil lands are formed, a metal nanoparticle paste produced as described above was printed with a metal mask having a thickness of 150 μm by use of a metal squeegee, and 10 tinned 1608CR chips were mounted on the printed films on the copper-foil lands. The 1608CR chips mounted on the glass epoxy substrate were bonded by reflow heating (with the reflow profile shown in FIG. 1 (oxygen concentration during reflow heating: 50 ppm or less) in Examples 1 to 8 and Comparative Examples 1, 3 to 4 wherein coated metal nanoparticles of tin were mixed, Comparative Example 2 wherein dry powder tin nanoparticles were mixed, Comparative Examples 5 and 6 wherein SAC305 soldering powder was mixed, and Example 11 wherein coated metal nanoparticles of tin, coated metal nanoparticles of silver and coated metal nanoparticles of copper were mixed such that the same composition as that of SAC305 soldering powder could be obtained; and with the reflow profile shown in FIG. 2 (oxygen concentration during reflow heating: 50 ppm or less) in Examples 9 and 10 wherein coated metal nanoparticles of silver or copper were mixed). Thereby a test piece was produced. With respect to the obtained test piece, the shearing strength of the 1608CR chips was measured with a tensile testing machine (EZ-L produced by SHIMADZU KK.) under the condition of 5 mm/min. The result was obtained by averaging the shearing strength values of the ten 1608CR chips.

### (III) Surface Condition:

With respect to the assemblies produced by the same process as described in the above (I) Chip resistance, the bonded parts between the substrates and the chips were visually observed. The following 4-grade evaluation was conducted.
⊚: smooth surface with metallic luster
◯: non-smooth surface with metallic luster
Δ: rough surface containing air bubbles with poor metallic luster
X: no change from the condition before heating, without metallic luster

The evaluation results of Examples 1 to 11 and Comparative Examples 1 to 6 are summarized in the following Table 2.

TABLE 2

| | Example | Example | Example | Example | Example | Example | Example | Example | Example | Example |
|---|---|---|---|---|---|---|---|---|---|---|
| | 1 | 2 | 3 | 4 | 5 | 6 | 7 | 8 | 9 | 10 |
| chip resistance [Ω] | 0.04 | 0.1 | 0.04 | 0.03 | 0.03 | 0.04 | 0.1 | 0.07 | 0.02 | 0.03 |
| shearing strength of | 8 | 2 | 7 | 3 | 4 | 7 | 2 | 3 | 9 | 6 |
| chip resistors [N] | | | | | | | | | | |
| surface condition | ◯ | Δ | ⊚ | ⊚ | ◯ | ◯ | Δ | Δ | ⊚ | ⊚ |

| | Example | Comparative | Comparative | Comparative | Comparative | Comparative | Comparative |
|---|---|---|---|---|---|---|---|
| | 11 | Example 1 | Example 2 | Example 3 | Example 4 | Example 5 | Example 6 |
| chip resistance [Ω] | 0.04 | non- | 0.1 | non- | non- | 0.1 | 0.1 |
| | | conductive | | conductive | conductive | | |
| shearing strength of | 10 | unmeasur- | unmeasur- | unmeasur- | unmeasur- | unmeasur- | unmeasur- |
| chip resistors [N] | | able | able | able | able | able | able |
| surface condition | ◯ | X | X | X | Δ | X | X |

With respect to the shearing strength in Table 2, “unmeasurable” indicates that shearing strength could not be measured since 1608CR chips could not be bonded onto the glass epoxy substrate.

As shown in Table 2, chip resistance was reduced and bonded parts with excellent electric conductivity could be obtained when a metal nanoparticle paste comprising metal nanoparticles coated with the sorbitan fatty acid ester and a carboxylic acid (Examples 1 to 4, 6 to 10), or a metal nanoparticle paste comprising metal nanoparticles coated with the oleyl amine and a carboxylic acid (Example 5), was used to bond the chips to the substrate. In Examples 1 to 10, the shearing strength of the chips bonded onto the substrate was increased, the mechanical strength of the bonded parts was enhanced, and also the surface condition of the bonded parts was good. As shown in Example 11, bonded parts with excellent electrical conductivity could be obtained by use of coated metal nanoparticles in a mixture consisting of three kinds of metal nanoparticles, and the surface condition of the bonded parts was also good. In Example 11, particularly the shearing strength of the chips was increased and the mechanical strength of the bonded parts was more enhanced, compared with Examples 1 to 10.

According to a comparison between Examples 1, 3 to 6, 8 to 11 versus Example 2, all of the electrical conductivity, shearing strength and surface condition of the bonded parts were more enhanced or improved by mixing diglycolic acid, diglycolic anhydride or octenyl succinic anhydride in a ratio of 30% by weight or more. Compared with the use of a monocarboxylic acid (Example 7), all of the electrical conductivity, shearing strength and surface condition of the bonded parts were more enhanced or improved by use of a dicarboxylic acid or an anhydride thereof (Examples 1, 5, 6, 8 to 11). As shown in Examples 9 and 10, the electrical conductivity and surface condition of the bonded parts were particularly excellent by use of squalane, which is a high-boiling point hydrocarbon-based solvent, as a dispersion medium for the coated metal nanoparticles of silver (Example 9) or copper (Example 10).

In Comparative Example 1, no protective film releasing agent such as a carboxylic acid was added to the protective film-coated metal nanoparticle paste, and in Comparative Examples 3 and 4, a protective film releasing agent other than carboxylic acids (e.g., an amine in Comparative Example 3, a halogen-based activator in Comparative Example 4) was added to a protective-film coated metal nanoparticle paste. In all the above examples, bonding was insufficient and bonded parts were not electrically conductive. As for the surfaces of the bonded parts, the condition was not good. As shown in Comparative Examples 2 and 6, chip resistance was high and the bonded parts were poorly conductive in the embodiment wherein a carboxylic acid was added to a paste of metal nanoparticles not coated with a protective film, or to a paste using a conventional soldering powder. In Comparative Examples 2, 5 and 6, bonding was insufficient and the surface condition of the bonded parts was poor, similarly to Comparative Examples 1, 3 and 4.

### Examples 12 to 14

### Comparative Example 7

In the following examples, the metal nanoparticle paste in accordance with the present invention was used as a wiring material.

(1) Components of Metal Nanoparticle Paste

### Electrically Conductive Material

Coated metal nanoparticles III and IV were the same as those described in the above examples wherein the metal nanoparticle paste was used as an electrically conductive bonding material. Metal nanoparticles VI were not coated with a protective film.

(2) Process for Producing Metal Nanoparticle Paste Used as Wiring Material:

A predetermined amount of a cyclohexane dispersion containing 20% by weight of coated metal nanoparticles obtained by the above activated continuous-interface vapor-deposition method, was poured into an agate mortar, and the contained cyclohexane was completely volatilized by drying under reduced pressure. Thereby coated metal nanoparticles containing 20% by weight of the protective film component were obtained. Predetermined amounts of a carboxylic acid and a solvent were added to the obtained coated metal nanoparticles, and the particles were mixed with a pestle for 5 minutes. Thereby a metal nanoparticle paste to be used as a wiring material was produced.

In accordance with the above process for producing a wiring material, the metal nanoparticle pastes of Examples 12 to 14 and Comparative Example 7 were prepared by mixing the components in the proportions as summarized in the following Table 3. The unit of the values of the mixing proportion is % by weight.

TABLE 3

| | | | | Example | Example | Example | Comparative |
|---|---|---|---|---|---|---|---|
| | | | | 12 | 13 | 14 | Example 7 |
| mixing | electrically | coated metal | metal: copper (mean | 40 | — | — | — |
| proportion | conductive | nanoparticles IV | primary particle | | | | |
| (% by | materials | | diameter 5.0 nm) | | | | |
| weight) | | coated metal | metal: silver (mean | — | 40 | 40 | — |
| | | nanoparticles III | primary particle | | | | |
| | | | diameter 4.6 nm) | | | | |
| | | coated metal | metal: copper (mean | — | — | — | 40 |
| | | nanoparticles VI | primary particle | | | | |
| | | | diameter 300 nm) | | | | |

| | | | | | |
|---|---|---|---|---|---|
| carboxylic acid | octenyl succinic anhydride | 20 | 20 | 20 | 20 |
| solvent | squalane | 40 | 40 | 40 | 40 |

| | | | | |
|---|---|---|---|---|
| total | 100 | 100 | 100 | 100 |

(3) Performance Evaluation

### (IV) Volume Resistance

Onto a slide glass, the metal nanoparticle paste prepared as described above was applied by screen printing in a size of 5 cm (length)×1 cm (width), the printed coating film was calcined under the conditions as shown in the following Table 4 (with a reflow profile shown in FIG. 2). The film thickness was thereafter measured and a value of resistance was measured by use of a micrometer produced by Iwatsu Keisoku K.K. to calculate the value of volume resistance (specific resistance).

The evaluation results of Examples 12 to 14 and Comparative Example 7 are summarized in the following Table 4.

TABLE 4

| | | | Example | Example | Example | Comparative |
|---|---|---|---|---|---|---|
| | | | 12 | 13 | 14 | Example 7 |
| calcination | ambience | gas composition | nitrogen | nitrogen | atmosphere | nitrogen |
| conditions | | oxygen concentration [ppm] | 50 | 50 | about 20% | 50 |
| | heating | temperature [° C.] | 300 | 300 | 300 | 300 |
| | conditions | time [min] | 10 | 10 | 10 | 10 |

| | | | | |
|---|---|---|---|---|
| Volume resistance (specific resistance) [Ω · cm] | 4.3E−04 | 8.9E−05 | 2.6E−06 | pattern could |
| | | | | not be formed |

*The specific resistance of a bulk copper: 1.67E−06 Ω · cm

As shown in Table 4, a wiring pattern with a suppressed value of volume resistance could be formed by adding a carboxylic acid to metal nanoparticles having a surface coated with the sorbitan fatty acid ester.

### Examples 15 to 19

### Comparative Examples 8 to 10

With respect to the metal nanoparticle paste according to the present invention, examples wherein the paste was used as a coating film/bonding material having a high reflectance are described below.

(1) Components of Metal Nanoparticle Paste

### Electrically Conductive Material

Coated metal nanoparticles III were the same as the coated metal nanoparticles III used in the above examples wherein the metal nanoparticle paste was used as an electrically conductive bonding material.

Silver powder was “AgC-A” produced by Fukuda Kinzoku K.K.

Dispersion Medium

Terpineol C: produced by Nippon Terpene K.K., a mixture of α-terpineol, β-terpineol and γ-terpineol, Existing Chemical Substance No. 3-2323, CAS. No. 8000-41-7, purity: 85% by weight or more

Dihydroterpineol: produced by Nippon Terpene K.K., a mixture of 1-hydroxy-p-menthane and 8-hydroxy-p-menthane, Existing Chemical Substance No. 3-2315, CAS. No. 498-81-7, purity: 96% by weight or more

(2) Process for Producing Coated Metal Nanoparticle Paste Used as Coating Film (Reflective Coating Film/LED Element Bonding Material) on Substrate

A predetermined amount of a cyclohexane dispersion containing 20% by weight of coated metal nanoparticles obtained by the above activated continuous-interface vapor-deposition method was poured into an agate mortar, and the contained cyclohexane was completely volatilized by drying under reduced pressure to form coated metal nanoparticles containing 20% by weight of the protective film component. Predetermined amounts of a carboxylic acid and a solvent were added to the obtained coated metal nanoparticles, and the content was mixed with a pestle for 5 minutes. Thereby, a metal nanoparticle paste to be used as a material for bonding an LED element onto a substrate was produced.

In accordance with the above production process, the metal nanoparticle pastes of Examples 15 to 19 and Comparative Examples 8 to 10 were produced. The components were mixed in the proportions, as shown in Table 5.

The unit of the values of the mixing proportion shown in Table 5 is % by weight.

TABLE 5

| | | | | Exam- | Exam- | Exam- | Exam- | Exam- | Comparative | Comparative | Comparative |
|---|---|---|---|---|---|---|---|---|---|---|---|
| | | | | ple 15 | ple 16 | ple 17 | ple 18 | ple 19 | Example 8 | Example 9 | Example 10 |
| mixing | electri- | coated | metal: silver | 70 | 70 | 70 | 70 | 70 | 70 | 70 | — |
| propor- | cally con- | metal nano- | (mean primary | | | | | | | | |
| tion | ductive | particles | particle | | | | | | | | |
| (% by | materials | III | diameter | | | | | | | | |
| weight) | | | 4.6 nm) | | | | | | | | |
| | | silver | mean particle | — | — | — | — | — | — | — | 70 |
| | | powder | diameter | | | | | | | | |
| | | | 3 μm* | | | | | | | | |

| | | | | | | | | | |
|---|---|---|---|---|---|---|---|---|---|
| carboxylic | octenyl succinic anhydride | 10 | 10 | 10 | 10 | 10 | 10 | 10 | 10 |
| acid | | | | | | | | | |
| solvents | Terpineol C | 20 | 20 | 20 | 20 | — | — | — | 20 |
| | Dihydroterpineol | — | — | — | — | 20 | — | — | — |
| | n-decane | — | — | — | — | — | 20 | — | — |
| | cyclohexane | — | — | — | — | — | — | 20 | — |

| | | | | | | | | |
|---|---|---|---|---|---|---|---|---|
| total | 100 | 100 | 100 | 100 | 100 | 100 | 100 | 100 |

(3) Performance Evaluation

### (V) Reflectance

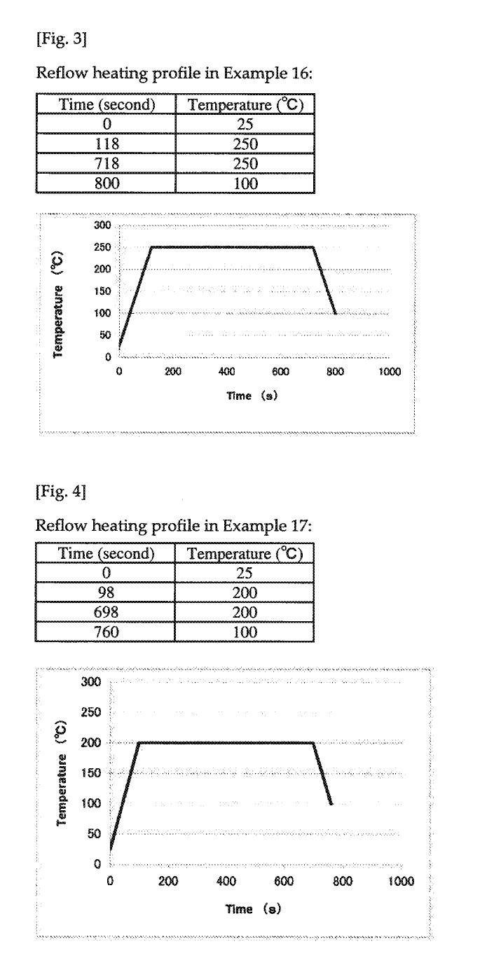

On a 6 cm×3 cm slide glass, the metal nanoparticle paste produced as described above was printed using a metal mask having a thickness of 200 μm with a metal squeegee. After the completion of printing, the slide glass was heated under the calcination conditions shown in the following Table 6 (of Examples 15 to 19 wherein coated metal nanoparticles of silver were used, Examples 15, 18, 19, and Comparative Examples 8 to 10 with the reflow profile shown in FIG. 2; Example 16 with the reflow profile shown in FIG. 3; Example 17 with the reflow profile shown in FIG. 4). Thereby, a 3 cm×2 cm metal coating film was formed on the slide glass. The reflectance of the above calcined metal coating film at 450 nm was measured with a spectrophotometer “HITACHI SPECTROPHOTOMETER U-4100” produced by HITACHI HIGH-TECH K.K. The maximum value of the reflectance within a range of from 250 to 800 nm was also measured. In the examples and comparative examples, the reflectance was measured at an incident angle of 10° for YAG laser. The reflectance was measured as a relative total luminous reflectance when assuming the reflectance at an incident angle of 10° to be 100, using alumina as an authentic sample (“Aluminum oxide standard white board” produced by HITACHI HIGH-TECH K.K.).

### (VI) Coating Film Condition:

Metal coating films formed by the same process as described in the above (V) were visually observed. A uniformly coated metal coating film without cracks was evaluated as “uniform”, and a metal coating film with cracks, which is unsuitable for practical use, was evaluated as “cracks”.

The volume resistance and the shearing strength of the chip resistors were measured by the processes as described in the above (IV) and (II), respectively.

The evaluation results of Examples 15 to 19 and Comparative Examples 8 to 10 are summarized in Table 6.

TABLE 6

| | | | Example | Example | Example | Example | Example | Comparative | Comparative | Comparative |
|---|---|---|---|---|---|---|---|---|---|---|
| | | | 15 | 16 | 17 | 18 | 19 | Example 8 | Example 9 | Example 10 |
| calcination | ambience | gas | atmo- | atmo- | atmo- | nitrogen | atmo- | atmo- | atmo- | atmo- |
| conditions | | composition | sphere | sphere | sphere | | sphere | sphere | sphere | sphere |
| | heating | temperature | 300 | 250 | 200 | 300 | 300 | 300 | 300 | 300 |
| | conditions | [° C.] | | | | | | | | |
| | | time [min] | 10 | 10 | 10 | 10 | 10 | 10 | 10 | 10 |

| coating film condition | | uniform | uniform | uniform | uniform | uniform | cracks | cracks | uniform |
|---|---|---|---|---|---|---|---|---|---|
| volume resistance (specific resistance) | | 3.8E−06 | 1.1E−05 | 3.4E−05 | 2.4E−05 | 4.3E−06 | 2.8E−04 | non | 1.4E−05 |
| [Ω · cm] | | | | | | | | conductive | |
| reflectance [%] | maximum value | 93 | 62 | 55 | 55 | 92 | 52 | 34 | 90 |
| | 450 nm | 92 | 60 | 55 | 45 | 91 | 48 | 31 | 88 |

| | | | | | | | | |
|---|---|---|---|---|---|---|---|---|
| shearing strength of chip resistors [N] | 40 | 39 | 18 | 22 | 41 | not | not | not |
| | | | | | | bonded | bonded | bonded |

As shown in Table 6, coating films having low volume resistance, high reflectance, and excellent shearing strength of chip resistors could be obtained by use of a coated metal nanoparticle paste comprising metal nanoparticles of silver and a terpene alcohol as a dispersion medium. As shown in Examples 15 to 19 and Comparative Examples 8 and 9, reflectance could be enhanced, while cracks of coating films could be prevented, by use of a terpene alcohol as a dispersion medium. By conducting calcination not in an inert gas ambience but in the atmosphere, the reflectance of the coating film could be more enhanced. In Examples 15 to 17 and 19, the reflectance of the coating film was more improved by heating at 250° C., particularly at 300° C.

### INDUSTRIAL APPLICABILITY

By use of the metal nanoparticle paste according to the present invention, an electronic component can be electrically bonded to a substrate by a heat treatment at a temperature lower than that of the melting point of the metal nanoparticles, and a wiring pattern can be formed on a substrate by the aforementioned low temperature heat treatment. The metal nanoparticle paste according to the present invention therefore has high potential in a field wherein an electronic component is mounted on a substrate. In addition, since the metal nanoparticle paste to which metal nanoparticles containing silver and a terpene alcohol were added has excellent reflectance and thermal conductivity, the paste has high potential particularly in use as a reflective coating film material for a substrate or a bonding material for an LED element.

1. A metal nanoparticle paste, comprising (A) metal nanoparticles, (B) a protective film that coats the surface of said metal nanoparticles, (C) a carboxylic acid, and (D) a dispersion medium.

2. The metal nanoparticle paste according to claim 1, wherein the metal nanoparticles (A) have a mean primary particle diameter of 1 to 100 nm.

3. The metal nanoparticle paste according to claim 1 or 2, wherein the metal nanoparticles (A) are particles of at least one metal selected from the group consisting of gold, silver, copper, platinum, palladium, nickel, bismuth, lead, indium, tin, zinc, titanium, aluminum and antimony.

4. The metal nanoparticle paste according to claim 1 or 2, wherein the metal nanoparticles (A) are particles of an alloy of at least one metal selected from the group consisting of gold, silver, copper, platinum, palladium, nickel, bismuth, lead, indium, tin, zinc, titanium, aluminum and antimony.

5. The metal nanoparticle paste according to claim 1, wherein the metal nanoparticles (A) are particles of tin having a mean primary particle diameter of 1 to 50 nm.

6. The metal nanoparticle paste according to claim 1, wherein the protective film (B) that coats the surface of metal nanoparticles, contains an organic compound having a group containing an oxygen atom, a nitrogen atom or a sulfur atom capable of coordinately bonding to the metal nanoparticles (A) via a lone-electron pair.

7. The metal nanoparticle paste according to claim 6, wherein the oxygen atom-containing group is a hydroxy group (—OH) or an oxy group (—O—), the nitrogen atom-containing group is an amino group (—NH₂), and the sulfur atom-containing group is a sulfanyl group (—SH).

8. The metal nanoparticle paste according to claim 6 or 7, wherein the organic compound having the oxygen atom-containing group is a compound represented by the following general formula (I): 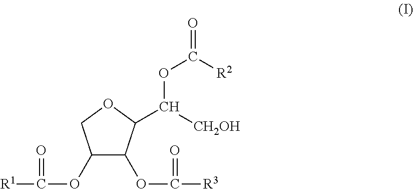
(wherein R¹, R² and R³ are each independently a C₂ to C₂₀ monovalent, and saturated or unsaturated hydrocarbon group).

9. The metal nanoparticle paste according to claim 6 or 7, wherein the organic compound having the nitrogen atom-containing group is a compound represented by the following general formula (IV):
R⁶—NH₂ (IV)
(wherein R⁶ is a C₂ to C₂₀ monovalent, and saturated or unsaturated hydrocarbon group).

10. The metal nanoparticle paste according to claim 1, wherein the carboxylic acid (C) is a monocarboxylic acid or an anhydride thereof, or a dicarboxylic acid or an anhydride thereof.

11. The metal nanoparticle paste according to claim 10, wherein the monocarboxylic acid is a compound represented by the following general formula (II):
R⁴—COOH (II)
(wherein R⁴ is a C₆ to C₁₀ monovalent, and saturated or unsaturated hydrocarbon group).

12. The metal nanoparticle paste according to claim 10, wherein the dicarboxylic acid is a compound represented by the following general formula (III):
HOOC—R⁵—COOH (III)
(wherein R⁵ is a C₁ to C₁₂ divalent group, which may have an ether bond).

13. The metal nanoparticle paste according to claim 1, wherein the metal nanoparticles (A) contain silver and the dispersion medium (D) is a terpene alcohol.

14. An electronic component assembly, wherein an electronic component is mounted on a substrate by use of the metal nanoparticle paste according to claim 1.

15. An LED module, wherein an LED element is bonded to a substrate by use of the metal nanoparticle paste according to claim 13.

16. A process for forming a circuit on a printed-wiring board, wherein an electrode and a wiring pattern are formed by a screen printing method or an ink-jet method by use of the metal nanoparticle paste according to claim 1, and wherein said wiring pattern is calcined by heating at a temperature of 250° C. or more.
